(19) United States
(12) Patent Application Publication
(10) Pub. No.: US 2023/0343685 A1
(43) Pub. Date: Oct. 26, 2023

(54) CORE SUBSTRATE AND INTERPOSER

(71) Applicant: NGK INSULATORS, LTD., Nagoya-Shi (JP)

(72) Inventors: Yoshitsugu WAKAZONO, Kyoto-Shi (JP); Makoto TANI, Inazawa-Shi (JP)

(73) Assignee: NGK INSULATORS, LTD., Nagoya-Shi (JP)

(21) Appl. No.: 18/342,878

(22) Filed: Jun. 28, 2023

Related U.S. Application Data
(63) Continuation of application No. PCT/JP2022/002456, filed on Jan. 24, 2022.

(30) Foreign Application Priority Data
Jan. 29, 2021 (WO) PCT/JP2021/003321

(51) Int. Cl. H01L 23/498; H05K 3/46; H05K 1/18; H01L 23/14

(52) U.S. Cl. CPC H01L 23/49822; H05K 3/4644; H05K 1/185; H01L 23/145

(57) ABSTRACT

A core substrate is a core substrate with a built-in inductor for constructing an interposer to which a semiconductor element is mounted. The core substrate includes: a ceramic substrate; a conductor portion; and a magnetic material portion. The ceramic substrate has a first surface, a second surface opposite the first surface in a thickness direction, and a through hole between the first surface and the second surface. The conductor portion extends through the through hole. The magnetic material portion surrounds the conductor portion within the through hole, and is made of ceramics. The conductor portion is made of sintered metal.

### BACKGROUND OF THE INVENTION

### Field of the Invention

The present invention relates to core substrates and interposers and, in particular, to a core substrate with a built-in inductor for constructing an interposer to which a semiconductor element is mounted.

### Description of the Background Art

According to Japanese Patent Application Laid-Open No. 2019-179792 (Patent Document 1), an interposer is disposed between a semiconductor element and a motherboard in a semiconductor device. The interposer and each of the semiconductor element and the motherboard are connected using solder balls. A multilayer wiring printed board is shown as the interposer, and includes a core substrate, three conductor circuit layers stacked over the core substrate to face the semiconductor element, and three conductor circuit layers stacked over the core substrate to face the motherboard. On a side of the interposer where the semiconductor element is mounted, a wiring dimension is reduced in stages by passing through the three conductor circuit layers.

Efficient power management is sometimes required for a semiconductor element for an integrated circuit (IC), for example. A supply voltage to each of a plurality of computing cores of a processor chip (the semiconductor element) is typically controlled by a voltage regulator in response to an amount of computation of a processor and the like. A switch, a capacitor, and an inductor are normally required to construct the voltage regulator. The switch, the capacitor, and the inductor are required for each of the computing cores to control the supply voltage for each of the computing cores. In particular, the inductor is difficult to be built in the semiconductor element, and thus is normally prepared separately from the semiconductor element. Use of a magnetic material is proposed to secure a sufficient inductance while suppressing a footprint for the inductor.

US Patent Application Publication No. 2019/0279806 (Patent Document 2) discloses a package substrate (a kind of interposer herein) disposed between a die (the semiconductor element) and a board (the motherboard). An inductor for the above-mentioned purpose is built in the package substrate. Specifically, the package substrate includes a substrate core, a conductive through hole through the substrate core, and a magnetic sheath around the conductive through hole. The magnetic sheath may include magnetic particles. The substrate core may be any substrate on which build-up layers (the conductor circuit layers) are formed. An organic material is shown as an example of the core substrate.

WO 2007/129526 (Patent Document 3) discloses a core substrate in which an inductor is disposed. As a method for manufacturing the inductor, a through hole is formed in an axial direction of a longitudinally extending magnetic body, and a conductor is formed on an inner surface of the through hole by metal plating. The conductor is formed to be hollow to release a stress caused by a difference in thermal expansion between the conductor and the magnetic body. As a method for embedding the inductor in the substrate, a through hole is formed in the substrate, the inductor is inserted into the through hole, and a space between the inductor and the substrate is filled with a resin.

(Patent Document 1: Japanese Patent Application Laid-Open No. 2019-179792)

(Patent Document 2: US Patent Application Publication No. 2019/0279806)

(Patent Document 3: WO 2007/129526)

A plurality of computing cores have recently been mounted to a die (the semiconductor element) to be joined to an interposer. In particular, a high-performance processor, such as that for a data server, includes many computing cores to increase computational processing capability, so that the number of computing cores per the area of the die is large, and the area of the die per computing core is small. To accommodate this, a high-density inductor having a larger inductance per unit area of the interposer is required.

US Patent Application Publication No. 2019/0279806 described above shows an example in which the substrate core mainly made of the organic material includes the conductive through hole (a conductor portion) and the magnetic sheath (a magnetic material portion) formed around the conductor portion and including the magnetic particles. In this case, the magnetic material portion is required to be formed at or below a heat resistant temperature of the organic material of the substrate core. As a typical technique satisfying the requirement, there is a technique of solidifying a resin in which the magnetic particles are dispersed. When the magnetic material portion includes the magnetic particles dispersed in the resin, however, a high permeability is less likely to be secured due to limitation of a filling factor of the magnetic particles (a proportion of the magnetic particles per volume). While the size of the inductor built in the interposer is required to be reduced in response to the above-mentioned densification of the interposer, a sufficient inductance is less likely to be secured when a dimension of each inductor is reduced by densification as permeability of the magnetic material portion is less likely to be increased as described above.

In WO 2007/129526 described above, the conductor (conductor portion) of the inductor is made of a plating film. In other words, plating is used as a method for forming the conductor portion. Due to this, variation of electrical characteristics (in particular, conductivity) of the conductor portion is likely to increase.

### SUMMARY

The present invention has been conceived to solve a problem as described above, and it is an object of the present invention to provide a core substrate with a built-in inductor for constructing an interposer to which a semiconductor element is mounted that includes the built-in inductor having a large inductance per unit area of the core substrate and has stable electrical characteristics.

A core substrate according to one aspect is a core substrate with a built-in inductor for constructing an interposer to which a semiconductor element is mounted, and includes a ceramic substrate, a conductor portion, and a magnetic material portion. The ceramic substrate has a first surface, a second surface opposite the first surface in a thickness direction, and a through hole between the first surface and the second surface. The conductor portion extends through the through hole. The magnetic material portion surrounds the conductor portion within the through hole, and is made of ceramics. The conductor portion is made of sintered metal.

According to the above-mentioned one aspect, the magnetic material portion is not made of a resin in which magnetic particles are dispersed but is made of ceramics. Permeability of the magnetic material portion can thereby sufficiently be increased by densely sintering the ceramics. The inductor having a large inductance per unit area can thus be built in the core substrate. The conductor portion is made of sintered metal. Variation of electrical characteristics of the conductor portion can thus be suppressed compared with a case where the conductor portion is a plating film. Electrical characteristics of the core substrate can thus be stabilized.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a cross-sectional view schematically showing a configuration of electronic equipment in Embodiment 1.

FIG. 2 is a cross-sectional view illustrating electronic equipment in a modification of FIG. 1.

FIG. 3 is a schematic diagram illustrating a configuration of inductors built in a core substrate in Embodiment 1 of the present invention.

FIG. 4 is a circuit diagram illustrating an example of electrical connection between a first inductor and a second inductor illustrated in FIG. 3.

FIG. 5 is a diagram schematically showing a configuration of the core substrate in Embodiment 1, and is a partial cross-sectional view taken along the line V-V of FIG. 6.

FIG. 6 is a partial cross-sectional view taken along the line VI-VI of FIG. 5.

FIG. 7 is a partial cross-sectional view illustrating a configuration of a core substrate in a comparative example.

FIG. 8 is a partial cross-sectional view schematically showing a configuration of a core substrate in Embodiment 2.

FIG. 9 is a partial cross-sectional view schematically showing a configuration of a core substrate in Embodiment 3.

FIG. 10 is a partial cross-sectional view schematically showing a configuration of a core substrate in Embodiment 4.

FIG. 11 is a partial cross-sectional view schematically showing a configuration of a core substrate in Embodiment 5.

FIG. 12 is a partial cross-sectional view schematically showing a configuration of a core substrate in Embodiment 6.

FIG. 13 is a partial cross-sectional view schematically showing a configuration of a core substrate in Embodiment 7.

FIG. 14 is a partial cross-sectional view schematically showing a configuration of a core substrate in Embodiment 8.

FIG. 15 is a partial cross-sectional view schematically showing a configuration of a core substrate in Embodiment 9.

FIG. 16 is a partial cross-sectional view schematically showing a configuration of a core substrate in Embodiment 10.

FIG. 17 is a diagram schematically showing a configuration of an interposer in Embodiment 11, and is a partial cross-sectional view taken along the line XVII-XVII of FIG. 18.

FIG. 18 is a partial plan view schematically showing a configuration of a second surface of the interposer in FIG. 17.

FIG. 19 is a diagram schematically showing a configuration of an interposer in Embodiment 12, and is a partial cross-sectional view taken along the line XIX-XIX of FIG. 20.

FIG. 20 is a partial plan view schematically showing a configuration of a second surface of the interposer in FIG. 19.

FIG. 21 is a partial plan view schematically showing a configuration of a core substrate in Embodiment 13.

FIG. 22 is a partial cross-sectional view taken along the line XXII-XXII of FIG. 21.

FIG. 23 is a partial plan view schematically showing a configuration of a core substrate in Embodiment 14.

FIG. 24 is a partial cross-sectional view taken along the line XXIV-XXIV of FIG. 23.

FIG. 25 is a partial plan view illustrating a modification of FIG. 23.

### DESCRIPTION OF THE PREFERRED EMBODIMENTS

Embodiments of the present invention will be described below based on the drawings.

### Embodiment 1

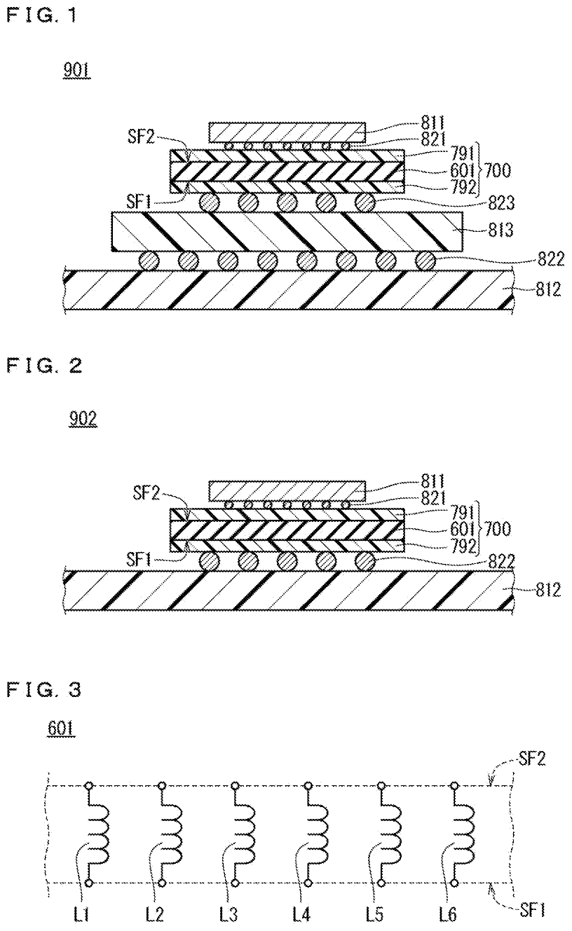

FIG. 1 is a cross-sectional view schematically showing a configuration of electronic equipment 901 in Embodiment 1. The electronic equipment 901 includes an interposer 700, a semiconductor element 811 (die), a motherboard 812, and a package substrate 813. The interposer 700 includes a core substrate 601, a wiring layer 791, and a wiring layer 792.

The wiring layer 792 and the wiring layer 791 are respectively stacked over one surface and the other surface (specifically, directly or indirectly over a first surface SF1 and a second surface SF2 described below) of the core substrate 601. The wiring layer 791 and the wiring layer 792 may be stacked over the core substrate 601 by build-up or sputtering, or may be joined as separate wiring boards.

The wiring layer 791 is preferably a multilayer wiring layer configured to have a wiring dimension (e.g., a line and space (L/S) dimension) reduced from a side facing the core substrate 601 to a side facing the semiconductor element 811. The interposer 700 to which the semiconductor element 811 having a small terminal pitch can be mounted can thereby be constructed even if a wiring (L/S) dimension of the core substrate 601 is not so high. Specifically, the wiring layer 791 may be a stack of a normal wiring layer facing the core substrate 601 and a fine wiring layer facing the semiconductor element 811.

The normal wiring layer may be formed by providing a wiring structure to a plate-like organic material (e.g., an epoxy-based member) or inorganic material (e.g., low temperature co-fired ceramics (LTCC) material or a non-magnetic ferrite material). Cu plating is used to form the wiring structure to the organic material, for example. To form the wiring structure to the inorganic material, the wiring structure is formed by firing of Ag (silver) or Cu (copper) simultaneously with formation of the inorganic material in a firing step.

The fine wiring layer is preferably formed by providing a wiring structure to a plate-like organic material (e.g., an epoxy-based or a polyimide-based member) in terms of ease of formation of fine wiring. Cu plating is used to form the wiring structure to the organic material, for example.

The semiconductor element 811 is mounted to the wiring layer 791 of the interposer 700. The semiconductor element 811 is connected to the wiring layer 791 of the interposer 700 by solder balls 821, for example. The semiconductor element 811 may be an integrated circuit (IC) chip. In particular, when the IC chip is a processor chip including a plurality of computing cores, the above-mentioned voltage regulator can be constructed using an inductor described below.

The interposer 700 is mounted to the package substrate 813 by joining the wiring layer 792 to the package substrate 813. The joining is achieved by solder balls 823, for example. The package substrate 813 is mounted to the motherboard 812, for example, by joining using solder balls 822.

According to the foregoing, an element side (a side facing the semiconductor element 811) of the interposer 700 is constructed by the wiring layer 791, and a substrate side (a side facing the package substrate 813 and the motherboard 812) of the interposer 700 is constructed by the wiring layer 792. A plurality of terminals (not illustrated) are provided to each of the element side and the substrate side of the interposer 700. A terminal pitch on the element side may be smaller than a terminal pitch on the substrate side, and, in this case, the interposer 700 has a function of transforming the terminal pitch. As a modification, either or both of the wiring layer 791 and the wiring layer 792 may be omitted in some applications of the interposer.

FIG. 2 is a cross-sectional view illustrating electronic equipment 902 as a modification of the electronic equipment 901 (FIG. 1). In the electronic equipment 902, the interposer 700 is joined to the motherboard 812 without the package substrate 813 (FIG. 1) interposed therebetween, and the joining is achieved by the solder balls 822, for example.

FIG. 3 is a schematic diagram illustrating a configuration of inductors built in the core substrate 601 in Embodiment 1 of the present invention. In the core substrate 601, a plurality of inductors L1 and L2 are built, inductors L3 to L6 and the like may further be built, and any number of inductors may be built. While a configuration of the inductors L1 and L2 will be described in detail below, the inductors L3 to L6 and the like may have a similar configuration.

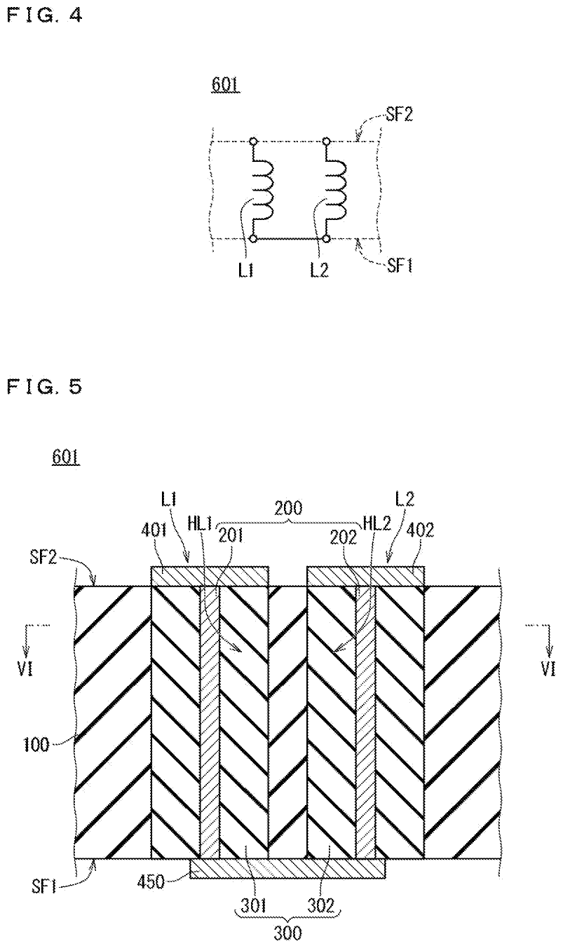

FIG. 4 is a circuit diagram illustrating an example of electrical connection between the inductors L1 and L2 illustrated in FIG. 3. In the present embodiment, the inductors L1 and L2 are connected in series to constitute an inductor having a combined inductance larger than an inductance of each of the inductors L1 and L2, and opposite ends of the inductor are arranged on the second surface SF2 to face the semiconductor element 811 (FIG. 1). The inductor having a sufficiently large inductance can thereby easily be connected to the semiconductor element 811. Electrical connection between the plurality of inductors built in the core substrate is not limited to that illustrated in FIG. 4, and may be designed as appropriate according to the application of the core substrate. A series structure of any number of inductors, a parallel structure of any number of inductors, or a combination thereof may thus be constructed.

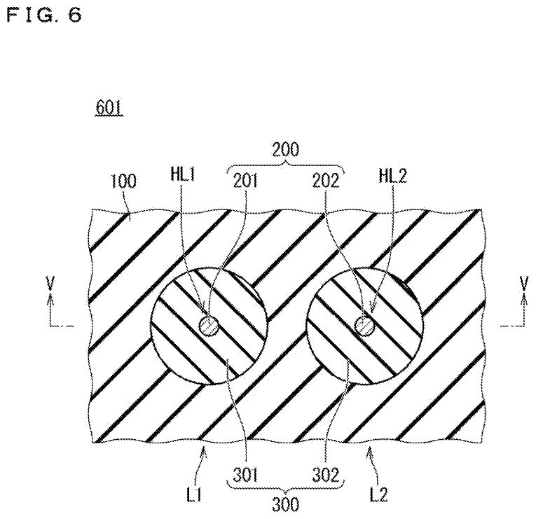

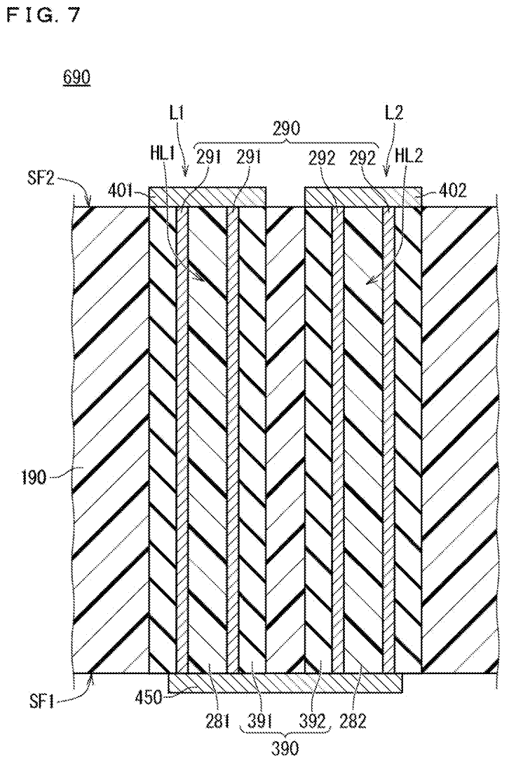

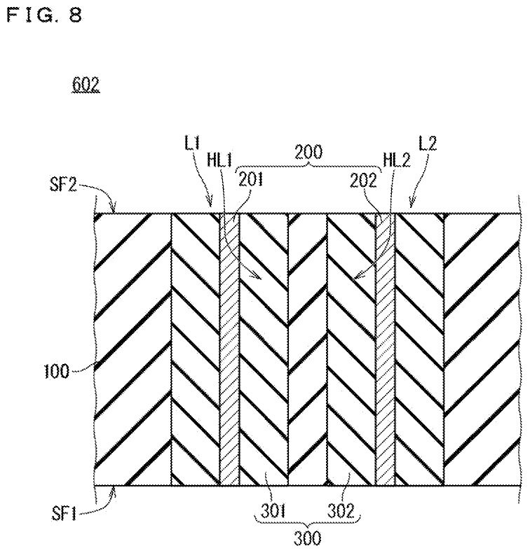

FIG. 5 is a diagram schematically showing a configuration of the core substrate 601 in Embodiment 1 of the present invention, and is a partial cross-sectional view taken along the line V-V of FIG. 6. FIG. 6 is a partial cross-sectional view taken along the line VI-VI of FIG. 5. As described above, the core substrate 601 is for constructing the interposer 700, and the inductors L1 and L2 are built in the core substrate 601. The core substrate 601 includes a ceramic substrate 100, a first conductor portion 201, a second conductor portion 202, a first magnetic material portion 301, a second magnetic material portion 302, a connecting portion 450, a terminal portion 401, and a terminal portion 402. The first conductor portion 201 and the second conductor portion 202 are also generically referred to as a conductor portion 200. The first magnetic material portion 301 and the second magnetic material portion 302 are also generically referred to as a magnetic material portion 300.

The ceramic substrate 100 has the first surface SF1 and the second surface SF2 opposite the first surface SF1 in a thickness direction. The ceramic substrate 100 is a substrate made of a ceramic sintered body. The ceramic sintered body does not substantially contain an organic component, and may contain a glass component. In other words, the ceramic substrate 100 may be made of glass ceramics. The ceramic substrate 100 is desirably made of LTCC. LTCC is ceramics that can be sintered at approximately 900° C. or less, and can be sintered at a temperature sufficiently lower than a melting point of Ag or Cu, so that LTCC can be sintered simultaneously with a built-in conductor containing Ag or Cu as a main component and having a low electrical resistance. The ceramic substrate 100 has a first through hole HL1 and a second through hole HL2 between the first surface SF1 and the second surface SF2. The ceramic substrate 100 preferably has a coefficient of thermal expansion of 4 ppm/° C. or more and 16 ppm/° C. or less. The ceramic substrate 100 preferably has a relative permittivity of 8 or less and a dissipation factor of 0.01 or less at 1 GHz.

The first conductor portion 201 and the second conductor portion 202 respectively extend through the first through hole HL1 and the second through hole HL2. The conductor portion 200 is a non-hollow body. In other words, the conductor portion 200 does not have a hollow interior. The conductor portion 200 is made of Ag and/or Cu, for example. The conductor portion 200 is made of sintered metal.

The first magnetic material portion 301 surrounds the first conductor portion 201 within the first through hole HL1. The second magnetic material portion 302 surrounds the second conductor portion 202 within the second through hole HL2. The first magnetic material portion 301 and the second magnetic material portion 302 may respectively be in direct contact with the first conductor portion 201 and the second conductor portion 202. The magnetic material portion 300 may have a circular inner edge and a circular outer edge in cross section (FIG. 6) perpendicular to the thickness direction. The inner edge and the outer edge may have another shape in place of the circular shape, and may have an elliptical shape or a polygonal shape, such as a quadrilateral shape, for example. Corners of the polygonal shape may be chamfered. Similarly, the first through hole HL1, the second through hole HL2, and the conductor portion 200 may each have another shape in cross section in place of the circular shape as illustrated in FIG. 6.

The magnetic material portion 300 is made of ceramics (a ceramic sintered body), and does not contain an organic component. To reduce the volume of the inductor, a magnetic material for the magnetic material portion 300 desirably has a high permeability, and the magnetic material portion 300 preferably has a compactness of 70% or more. To reduce an electrical loss of the inductor, the magnetic material for the magnetic material portion 300 is desirably a soft magnetic material having a small magnetic loss at a high frequency, and is desirably a soft magnetic material having a magnetic loss tangent of 0.1 or less at a frequency of 100 MHz, for example. To reduce a magnetic loss at a high frequency, the magnetic material for the magnetic material portion 300 desirably has a high volume electrical resistivity, and, specifically, is desirably an electrical insulator. The magnetic material portion 300 is preferably made of a ferrite-based material, a crystalline structure of the material is preferably a spinel structure in terms of ease of manufacture, Ni—Zn-based ferrite or Ni—Zn—Cu-based ferrite is used, for example, and the crystalline structure of the material is preferably a hexagonal structure having a c-axis orientation along the thickness direction (a vertical direction in FIG. 5) in terms of a high permeability.

A method for manufacturing the core substrate 601 includes a firing step. In the firing step, the conductor portion 200 (the first conductor portion 201 and the second conductor portion 202) and the magnetic material portion 300 (the first magnetic material portion 301 and the second magnetic material portion 302) are fired simultaneously with the ceramic substrate 100. The conductor portion 200 and the magnetic material portion 300 are thus bonded together without an organic material interposed therebetween. In other words, the conductor portion 200 and the magnetic material portion 300 are inorganically bonded together. Specifically, the conductor portion 200 and the magnetic material portion 300 are sintered together.

The connecting portion 450 electrically connects one end of the first conductor portion 201 and one end of the second conductor portion 202 on the first surface SF1 of the ceramic substrate 100. On the second surface SF2 of the ceramic substrate 100, the terminal portion 401 is connected to the other end of the first conductor portion 201, and the terminal portion 402 is connected to the other end of the second conductor portion 202. The terminal portion 401 and the terminal portion 402 are away from each other. Thus, the one end of the first conductor portion 201 and the one end of the second conductor portion 202 are electrically connected to each other, and the other end of the first conductor portion 201 and the other end of the second conductor portion 202 are electrically separated from each other. A circuit illustrated in FIG. 4 is thereby constructed.

A design example of the core substrate 601 (FIGS. 5 and 6) will be described below. The ceramic substrate 100 has a square shape with sides of 50 mm in an in-plane direction, and has a dimension of 550 μm in the thickness direction. The plurality of through holes (the first through hole HL1, the second through hole HL2, and the like) are arranged at a pitch of 450 μm. The ceramic substrate 100 is made of an LTCC material containing a Ba—Si—Al—O element as a main component or glass alumina, for example. The magnetic material portion 300 (FIG. 6) has an outer diameter of 350 μm and an inner diameter of 100 μm. The conductor portion 200 has an outer diameter of 100 μm. The conductor portion 200 is formed by sintering of Ag powder. The magnetic material portion 300 is made of a ferrite sintered body, and assume that relative permeability thereof is estimated to be 16. In this case, a single inductor (e.g., the inductor L1) has an inductance of approximately 2 nH at 140 MHz according to estimates of the inventors.

FIG. 7 is a partial cross-sectional view illustrating a configuration of a core substrate 690 in a comparative example. In the core substrate 690, the first through hole HL1 and the second through hole are formed in a resin substrate 190 made of a glass epoxy resin. A first magnetic material portion 391 and a first conductor portion 291 are formed in order over a side wall of the first through hole HL1, and the first conductor portion 291 has a hollow structure filled with a resin material 281. Similarly, a second magnetic material portion 392 and a second conductor portion 292 are formed in order over a side wall of the second through hole HL2, and the second conductor portion 292 has a hollow structure filled with a resin material 282. The first conductor portion 291 and the second conductor portion 292 are also generically referred to as a conductor portion 290.

As described above, the first magnetic material portion 391 and the second magnetic material portion 392 (also generically referred to as a magnetic material portion 390) are formed within the resin substrate 190. A step of forming the magnetic material portion 390 is thus required to be performed at or below a heat resistant temperature of the resin substrate 190. With this constraint, the magnetic material portion 390 is not made of a ceramic sintered body but is made of a resin in which magnetic particles are dispersed. In this case, a gap between the magnetic particles in the magnetic material portion 390 is filled with a resin, and it is normally difficult to increase a filling factor thereof to 70% or more. As a result, relative permeability of the first magnetic material portion 391 and the second magnetic material portion 392 is more difficult to be increased compared with relative permeability of the first magnetic material portion 301 and the second magnetic material portion 302 (FIG. 5), and is approximately 6, for example.

A design example of the core substrate 690 will be described below. The resin substrate 190 has a square shape with sides of 50 mm in the in-plane direction, and has a dimension of 1000 μm in the thickness direction. The plurality of through holes (the first through hole HL1, the second through hole HL2, and the like) are arranged at a pitch of 500 μm. The magnetic material portion 390 has an outer diameter of 400 μm and an inner diameter of 200 μm. The conductor portion 290 has an outer diameter of 200 μm. The conductor portion 290 is formed by Cu plating. The magnetic material portion 390 is made of the resin in which the magnetic particles are dispersed, and assume that relative permeability thereof is estimated to be 6. A single inductor (e.g., the inductor L1) in this case has an inductance of approximately 1 nH at 140 MHz according to estimates of the inventors. The value is half the value estimated to be approximately 2 nH in the present embodiment.

According to the present embodiment, the magnetic material portion 300 (FIG. 5) is not made of a resin in which magnetic particles are dispersed as with the magnetic material portion 390 (FIG. 7) but is made of the ceramic sintered body. Permeability of the magnetic material portion 300 can thereby sufficiently be increased by densely sintering the ceramics. The inductor having a large inductance per unit area can thus be built in the core substrate 601. The conductor portion 200 is made of sintered metal. Variation of electrical characteristics, in particular, conductivity of the conductor portion 200 can thus be suppressed compared with a case where the conductor portion 200 is a plating film. Electrical characteristics of the core substrate can thus be stabilized.

The conductor portion 200 is the non-hollow body. Electrical resistance of the conductor portion 200 can thereby be reduced.

The conductor portion 200 and the magnetic material portion 300 are bonded together without an organic material interposed therebetween. In other words, the conductor portion 200 and the magnetic material portion 300 are inorganically bonded together. Specifically, the conductor portion 200 and the magnetic material portion 300 are sintered together. Heat resistance of the core substrate 601 can thereby be increased compared with a case where the conductor portion 200 and the magnetic material portion 300 are bonded together via an organic material.

The ceramic substrate 100 (FIG. 5) has a higher stiffness than the resin substrate 190 (FIG. 7). The ceramic substrate 100 is thus less likely to warp even after addition of another member to the ceramic substrate 100. The core substrate 601 having smaller warpage can thus be obtained. By suppressing warpage, the formation yield of the wiring layer 791 and the wiring layer 792 (FIG. 1), in particular, the yield of the wiring layer 791 including the wiring structure having a high density is improved first. Second, the mounting yield of the semiconductor element 811 (FIG. 1) is improved.

When the magnetic material portion 300 has the circular inner edge and the circular outer edge in cross section (FIG. 6) perpendicular to the thickness direction, the magnetic material portion 300 can be disposed isotropically with respect to the conductor portion 200 in the cross section.

When the magnetic material portion 300 has a compactness of 70% or more, permeability of the magnetic material portion 300 is likely to be sufficiently increased.

When the ceramic substrate 100 has a coefficient of thermal expansion of 4 ppm/° C. or more and 16 ppm/° C. or less, the coefficient of thermal expansion of the ceramic substrate 100 is between the coefficient of thermal expansion of the semiconductor element 811 (FIG. 1) to be mounted to the interposer 700 including the core substrate 601 and the coefficient of thermal expansion of the typical motherboard 812 (FIG. 1) to which the interposer 700 is to be mounted. Warpage in the electronic equipment 901 (FIG. 1) or the electronic equipment 902 (FIG. 2) due to thermal expansion and contraction can thereby be suppressed.

When the magnetic material portion 300 is made of an insulator, diffusion of a current from the conductor portion 200 to the magnetic material portion 300 can be avoided even when the magnetic material portion 300 is in direct contact with the conductor portion 200 as illustrated in FIGS. 5 and 6.

When the magnetic material portion 300 is in direct contact with the conductor portion 200, a region in which the magnetic material portion 300 is disposed is likely to be sufficiently secured.

The core substrate 601 includes the inductor L1 including the first conductor portion 201 and the first magnetic material portion 301 and the inductor L2 including the second conductor portion 202 and the second magnetic material portion 302. The plurality of inductors can thereby be built in the core substrate 601.

The connecting portion 450 electrically connects the one end (a lower end in FIG. 5) of the first conductor portion 201 and the one end (a lower end in FIG. 5) of the second conductor portion 202 on the first surface SF1 of the ceramic substrate 100. The inductor L1 including the first conductor portion 201 and the first magnetic material portion 301 and the inductor L2 including the second conductor portion 202 and the second magnetic material portion 302 can thereby electrically be connected to each other.

When the other end (an upper end in FIG. 5) of the first conductor portion 201 and the other end (an upper end in FIG. 5) of the second conductor portion 202 are electrically separated from each other as illustrated in FIG. 5, the inductor L1 including the first conductor portion 201 and the first magnetic material portion 301 and the inductor L2 including the second conductor portion 202 and the second magnetic material portion 302 are connected not in parallel but in series. The combined inductance can thus be increased.

### Embodiment 2

FIG. 8 is a partial cross-sectional view schematically showing a configuration of a core substrate 602 in Embodiment 2. The core substrate 602 does not include the connecting portion 450 (FIG. 5: Embodiment 1). The core substrate 602 also does not include the terminal portion 401 and the terminal portion 402 (FIG. 5: Embodiment 1). The other configuration is substantially the same as the above-mentioned configuration in Embodiment 1, so that the same or corresponding components bear the same reference signs, and description thereof is not repeated. According to the core substrate 602 in the present embodiment, the configuration can be simplified compared with that of the core substrate 601 (FIG. 5: Embodiment 1) while the inductors L1 and L2 are built as in the core substrate 601.

### Embodiment 3

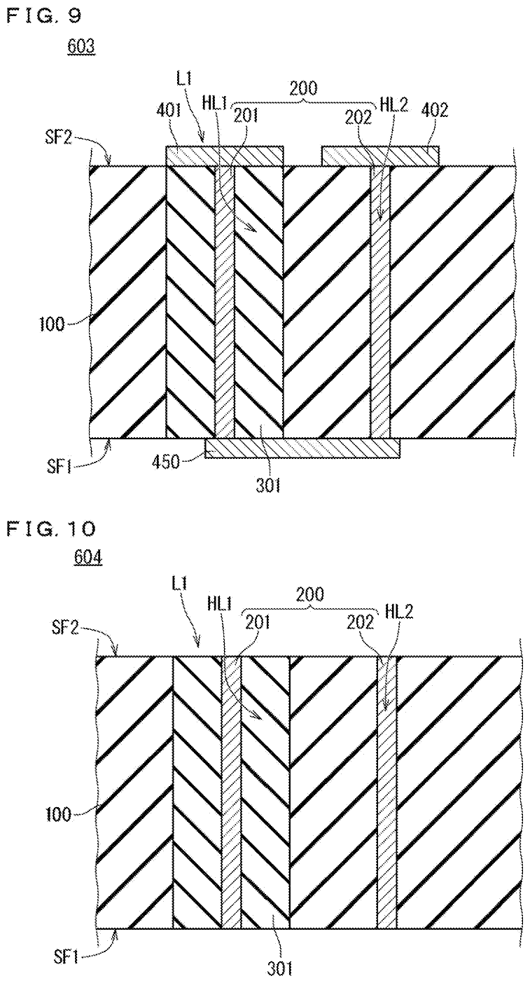

FIG. 9 is a partial cross-sectional view schematically showing a configuration of a core substrate 603 in Embodiment 3. The core substrate 603 does not include the second magnetic material portion 302 (FIG. 5: Embodiment 1). The other configuration is substantially the same as the above-mentioned configuration in Embodiment 1, so that the same or corresponding components bear the same reference signs, and description thereof is not repeated. Also in the core substrate 603 in the present embodiment, the inductor can be disposed between the terminal portion 401 and the terminal portion 402 as in the core substrate 601 (FIG. 5: Embodiment 1). The inductor includes the inductor L1 as in Embodiment 1, but does not include the inductor L2 (FIG. 5) in contrast to Embodiment 1.

### Embodiment 4

FIG. 10 is a partial cross-sectional view schematically showing a configuration of a core substrate 604 in Embodiment 4. The core substrate 604 does not include the connecting portion 450 (FIG. 9: Embodiment 3). The core substrate 604 also does not include the terminal portion 401 and the terminal portion 402 (FIG. 9: Embodiment 3). The other configuration is substantially the same as the above-mentioned configuration in Embodiment 3, so that the same or corresponding components bear the same reference signs, and description thereof is not repeated. According to the core substrate 604 in the present embodiment, the configuration can be simplified compared with that of the core substrate 603 (FIG. 9: Embodiment 3) while the inductor L1 is built as in the core substrate 603.

### Embodiment 5

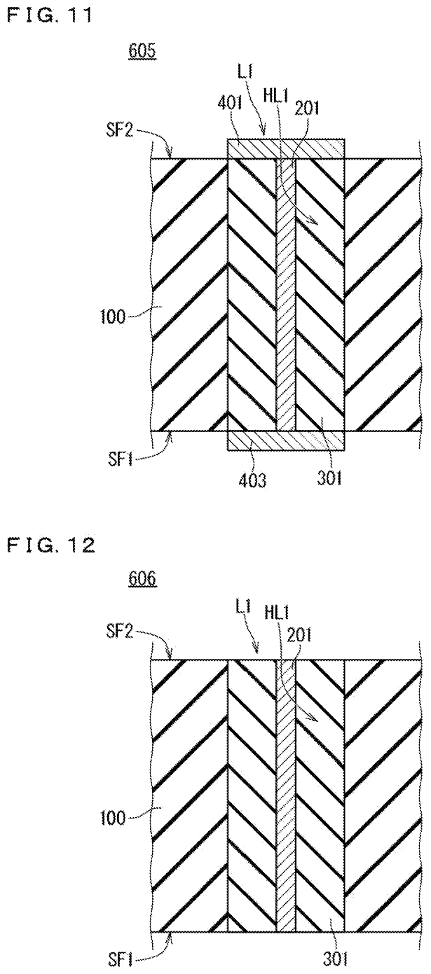

FIG. 11 is a partial cross-sectional view schematically showing a configuration of a core substrate 605 in Embodiment 5. The core substrate 605 does not include the connecting portion 450 and the second conductor portion 202 (FIG. 9: Embodiment 3). The core substrate 605 includes a terminal portion 403 connected to the one end of the first conductor portion 201 on the first surface in place of the terminal portion 402 on the second surface SF2. The other configuration is substantially the same as the above-mentioned configuration in Embodiment 3, so that the same or corresponding components bear the same reference signs, and description thereof is not repeated. According to the core substrate 605 in the present embodiment, the configuration can be simplified compared with that of the core substrate 603 (FIG. 9: Embodiment 3) while the inductor L1 is built as in the core substrate 603.

### Embodiment 6

FIG. 12 is a partial cross-sectional view schematically showing a configuration of a core substrate 606 in Embodiment 6. The core substrate 606 does not include the terminal portion 401 and the terminal portion 403 (FIG. 11: Embodiment 5). The other configuration is substantially the same as the above-mentioned configuration in Embodiment 5, so that the same or corresponding components bear the same reference signs, and description thereof is not repeated. According to the core substrate 606 in the present embodiment, the configuration can be simplified compared with that of the core substrate 605 (FIG. 11: Embodiment 5) while the inductor L1 is built as in the core substrate 605.

### Embodiment 7

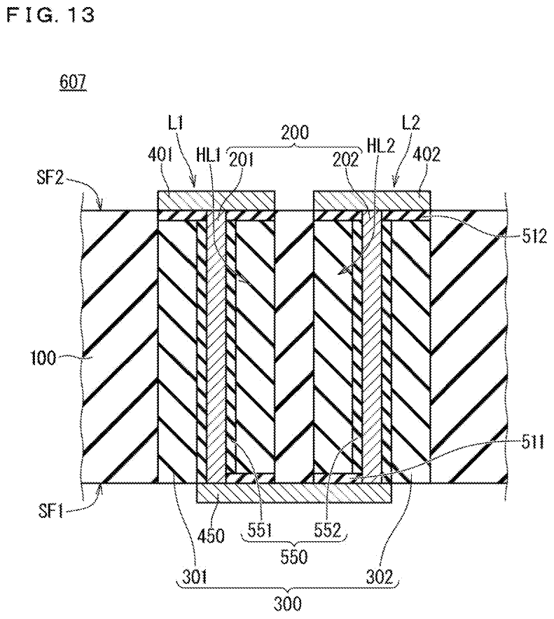

FIG. 13 is a partial cross-sectional view schematically showing a configuration of a core substrate 607 in Embodiment 7.

The core substrate 607 includes a plurality of insulator ceramic films 550 including a first insulator ceramic film 551 and a second insulator ceramic film 552. The first insulator ceramic film 551 separates the first magnetic material portion 301 from the first conductor portion 201. The second insulator ceramic film 552 separates the second magnetic material portion 302 from the second conductor portion 202.

The core substrate 607 includes an insulator layer 511 at least partially covering each of the first magnetic material portion 301 and the second magnetic material portion 302 along a plane including the first surface SF1 of the ceramic substrate 100. The insulator layer 511 separates the connecting portion 450 and each of the first magnetic material portion 301 and the second magnetic material portion 302. The insulator layer 511 may partially cover each of the first magnetic material portion 301 and the second magnetic material portion 302 as illustrated.

The core substrate 607 includes an insulator layer 512 at least partially covering each of the first magnetic material portion 301 and the second magnetic material portion 302 along a plane including the second surface SF2 of the ceramic substrate 100. The insulator layer 512 separates the first magnetic material portion 301 and the terminal portion 401, and separates the second magnetic material portion 302 and the terminal portion 402. The insulator layer 512 may entirely cover each of the first magnetic material portion 301 and the second magnetic material portion 302 as illustrated.

The insulator layer 511 and the insulator layer 512 may be made of a non-magnetic material. The insulator layer 511 and the insulator layer 512 are made of an inorganic material, an organic material, or a mixture thereof. The inorganic material may be the same as or different from a material for the ceramic substrate 100. The insulator ceramic films 550 may be made of a non-magnetic material. A material for the insulator ceramic films 550 may be the same as or different from the material for the ceramic substrate 100. A material for the insulator layer 511, a material for the insulator layer 512, and the material for the insulator ceramic films 550 may be different from one another, but are preferably a common material. The common material may be the same as or different from the material for the ceramic substrate 100.

The other configuration is substantially the same as the above-mentioned configuration in Embodiment 1, so that the same or corresponding components bear the same reference signs, and description thereof is not repeated.

According to the present embodiment, the insulator ceramic films 550 separate the magnetic material portion 300 from the conductor portion 200. An adverse effect due to direct contact between the conductor portion 200 and the magnetic material portion 300 can thereby be avoided. In particular, when the magnetic material portion 300 has non-negligible conductivity (in particular, when the magnetic material portion 300 is a conductor), diffusion of a current from the conductor portion 200 to the magnetic material portion 300 can be prevented.

### Embodiment 8

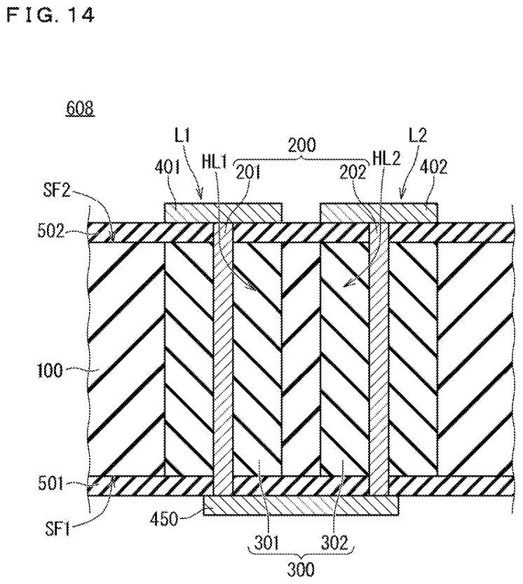

FIG. 14 is a partial cross-sectional view schematically showing a configuration of a core substrate 608 in Embodiment 8.

The core substrate 608 includes an insulator layer 501 at least partially covering each of the first magnetic material portion 301 and the second magnetic material portion 302 along a plane including the first surface SF1 of the ceramic substrate 100. The insulator layer 501 separates the connecting portion 450 and each of the first magnetic material portion 301 and the second magnetic material portion 302. The insulator layer 501 may entirely cover the first magnetic material portion 301 and the second magnetic material portion 302 along the plane including the first surface SF1 as illustrated.

The core substrate 608 includes an insulator layer 502 at least partially covering each of the first magnetic material portion 301 and the second magnetic material portion 302 along a plane including the second surface SF2 of the ceramic substrate 100. The insulator layer 502 separates the first magnetic material portion 301 and the terminal portion 401, and separates the second magnetic material portion 302 and the terminal portion 402. The insulator layer 502 may entirely cover the first magnetic material portion 301 and the second magnetic material portion 302 along the plane including the second surface SF2 as illustrated.

The insulator layer 501 and the insulator layer 502 may be made of a non-magnetic material. The insulator layer 501 and the insulator layer 502 are made of an inorganic material, an organic material, or a mixture thereof. The inorganic material may be the same as or different from the material for the ceramic substrate 100. A material for the insulator layer 501 and a material for the insulator layer 502 may be different from each other, but are preferably a common material. The common material may be the same as or different from the material for the ceramic substrate 100.

The other configuration is substantially the same as the above-mentioned configuration in Embodiment 1, so that the same or corresponding components bear the same reference signs, and description thereof is not repeated.

According to the present embodiment, the insulator layer 501 at least partially covers the magnetic material portion 300 along the plane including the first surface SF1 of the ceramic substrate 100. An effect between the magnetic material portion 300 and a configuration over the first surface SF1 can thereby be suppressed. Furthermore, the insulator layer 502 at least partially covers the magnetic material portion 300 along the plane including the second surface SF2 of the ceramic substrate 100. An effect between the magnetic material portion 300 and a configuration over the second surface SF2 can thereby be suppressed.

### Embodiment 9

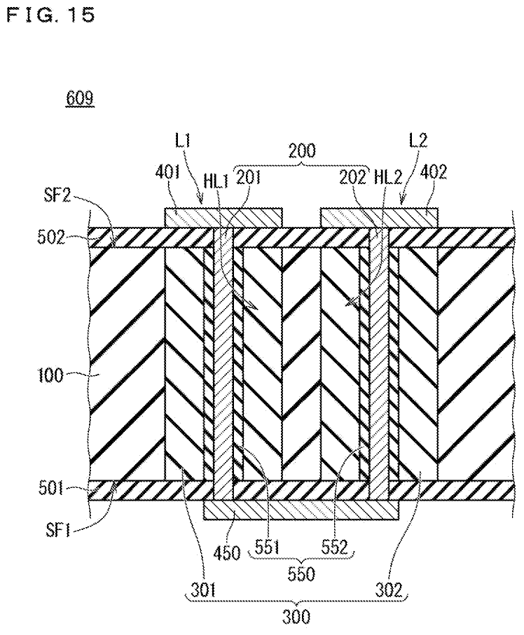

FIG. 15 is a partial cross-sectional view schematically showing a configuration of a core substrate 609 in Embodiment 9. The core substrate 609 includes the insulator ceramic films 550 (FIG. 13: Embodiment 7) in addition to the configuration of the core substrate 608 (FIG. 14: Embodiment 8). The materials for the insulator layer 501 and the insulator layer 502 may be the same as or different from the material for the ceramic substrate 100. In each of the former case and the latter case, the material for the insulator ceramic films 550 may be the same as or different from the material for the ceramic substrate 100.

The other configuration is substantially the same as the above-mentioned configuration in Embodiment 7 or 8, so that the same or corresponding components bear the same reference signs, and description thereof is not repeated.

### Embodiment 10

In each of the core substrate 608 (FIG. 14: Embodiment 8) and the core substrate 609 (FIG. 15: Embodiment 9) described above, a boundary surface between the conductor portion 200 and the connecting portion 450 and a boundary surface between the insulator layer 501 and the connecting portion 450 are substantially coplanar with each other. Also in each of the core substrate 608 and the core substrate 609, a boundary surface between the terminal portion 401 and the first conductor portion 201 and a boundary surface between the terminal portion 401 and the insulator layer 502 are substantially coplanar with each other, and a boundary surface between the terminal portion 402 and the second conductor portion 202 and a boundary surface between the terminal portion 402 and the insulator layer 502 are substantially coplanar with each other. Arrangement of the boundary surfaces, however, is not limited to this arrangement. For example, Embodiment 9 described above and Embodiment 10 described below differ in arrangement of the boundary surfaces.

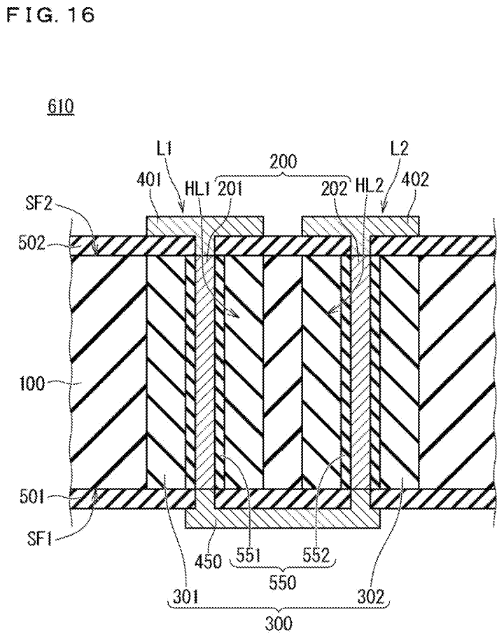

FIG. 16 is a partial cross-sectional view schematically showing a configuration of a core substrate 610 in Embodiment 10. In the core substrate 610, the boundary surface between the conductor 200 and the connecting portion 450 is substantially coincident with the first surface SF1 of the ceramic substrate 100. The boundary surface between the terminal portion 401 and the first conductor portion 201 and the boundary surface between the terminal portion 402 and the second conductor portion 202 are each substantially coincident with the second surface SF2 of the ceramic substrate 100.

The above-mentioned boundary surface between the conductor portion 200 and a wiring portion connected thereto (the connecting portion 450, the terminal portion 401, the terminal portion 402, the terminal portion 403, and the like in the present embodiment and the other embodiments) may be a microscopically observable boundary surface, but may alternatively be an imaginary boundary surface. The imaginary boundary surface may be assumed irrespective of the microscopically observable boundary surface.

### Embodiment 11

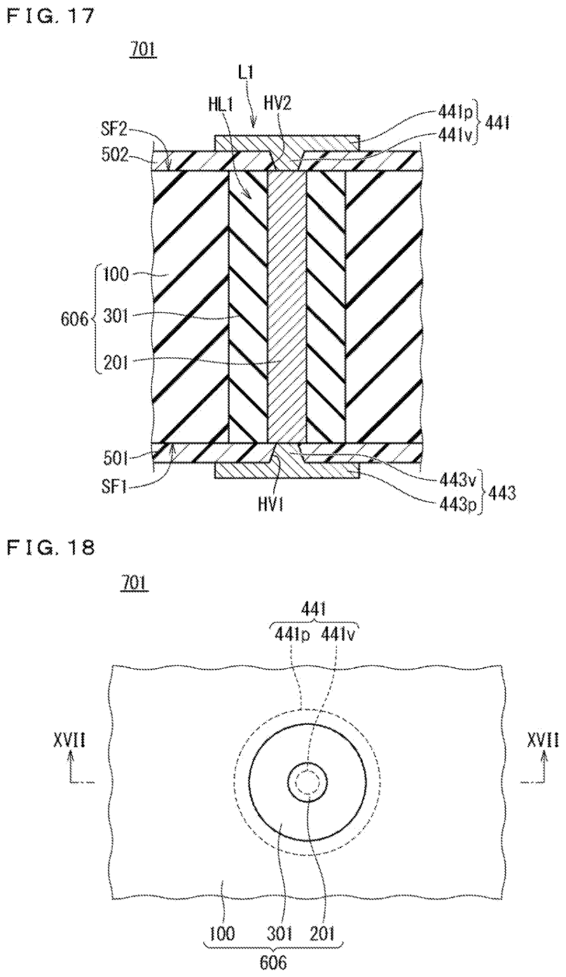

FIG. 17 is a diagram schematically showing a configuration of an interposer 701 in Embodiment 11, and is a partial cross-sectional view taken along the line XVII-XVII of FIG. 18. FIG. 18 is a partial plan view schematically showing a configuration of the second surface SF2 of the interposer 701 in FIG. 17. The interposer 701 is one example of the interposer 700 (FIG. 1 or 2). Specifically, the interposer 701 includes the core substrate 606 (FIG. 12: Embodiment 6), a wiring portion 441 and the insulator layer 502 as the wiring layer 791 (FIG. 1 or 2), and a wiring portion 443 and the insulator layer 501 as the wiring layer 792 (FIG. 1 or 2). In FIG. 18, the configuration of the core substrate 606 is indicated by solid lines, and another configuration added to the core substrate 606 is indicated by dashed lines for clarity of illustration.

The wiring portion 441 includes a wiring pattern 441p and a connecting via 441v. The connecting via 441v has a bottom surface connected to the first conductor portion 201 of the core substrate 606. The bottom surface of the connecting via 441v is separated from the first magnetic material portion 301 and the ceramic substrate 100. While a pattern layout of the wiring pattern 441p is circular in FIG. 18, a shape of the pattern layout is not limited to this shape, and the pattern layout may be designed as appropriate in response to a circuit configuration required for the interposer 701.

Similarly, the wiring portion 443 includes a wiring pattern 443p and a connecting via 443v. The connecting via 443v has a bottom surface connected to the first conductor portion 201 of the core substrate 606. The bottom surface of the connecting via 443v is separated from the first magnetic material portion 301 and the ceramic substrate 100. A pattern layout of the wiring pattern 443p may be designed as appropriate in response to the circuit configuration required for the interposer 701.

The insulator layer 502 has a via hole HV2 in which the connecting via 441v is disposed. The via hole HV2 is preferably tapered toward the first conductor portion 201 as illustrated in FIG. 17, but a shape of the via hole HV2 is no limited to this shape, and the via hole HV2 may be straight. The insulator layer 502 separates the wiring portion 441 and each of the first magnetic material portion 301 and the ceramic substrate 100 of the core substrate 606. The insulator layer 502 preferably contains organic matter, may be an organic insulator layer, and may be an epoxy-based resin layer, for example.

Similarly, the insulator layer 501 has a via hole HV1 in which the connecting via 443v is disposed. The via hole HV1 is preferably tapered toward the first conductor portion 201 as illustrated in FIG. 17, but a shape of the via hole HV1 is no limited to this shape, and the via hole HV1 may be straight. The insulator layer 501 separates the wiring portion 443 and each of the first magnetic material portion 301 and the ceramic substrate 100 of the core substrate 606. The insulator layer 501 preferably contains organic matter, may be an organic insulator layer, and may be an epoxy-based resin layer, for example.

The wiring portion 441 may be a plating layer. In this case, the wiring portion 441 and the insulator layer 502 may be formed by a semi-additive method, and may generally be formed as described below, for example. An organic insulating film as the insulator layer 502 not having the via hole HV2 yet is attached to the second surface SF2 of the core substrate 606. Next, the via hole HV2 is formed by laser processing. Next, a seed layer is formed on a surface of the insulator layer 502 including an inner surface of the via hole HV2 by electroless copper plating. Next, a plating resist exposing a region in which the wiring pattern 441p of the wiring portion 441 is to be formed is formed over the insulator layer 502. Next, electrolytic copper plating is performed using the seed layer and the plating resist described above. Next, the plating resist is stripped. The wiring portion 441 is formed as described above. The wiring portion 443 and the insulator layer 501 may similarly be formed.

According to the present embodiment, the bottom surface of the connecting via 441v is separated from the magnetic material portion 301 and the ceramic substrate 100. Specifically, the insulator layer 502 separates the wiring portion 441 and each of the first magnetic material portion 301 and the ceramic substrate 100 of the core substrate 606. Inclusion of components of the first magnetic material portion 301 and the ceramic substrate 100 into the wiring portion 441 can thereby be avoided. Specifically, elution of components of the first magnetic material portion 301 and the ceramic substrate 100 into a plating solution to form the plating layer as the wiring portion 441 can be avoided. Variation of electrical characteristics (in particular, conductivity) of the wiring portion 441 can thereby be suppressed. The same applies to the wiring portion 443.

When the via hole HV2 of the insulator layer 502 is tapered toward the first conductor portion 201, the size of the via hole HV2 can be larger at a position away from the first conductor portion 201 while a configuration as described above is secured. Electrical resistance of the connecting via 441v disposed therein can thereby be reduced. The same applies to the via hole HV1 of the insulator layer 501.

When the insulator layer 502 contains organic matter (in particular, when the insulator layer 502 is an organic insulator layer), inclusion of components of the first magnetic material portion 301 and the ceramic substrate 100 into the wiring portion 441 is more likely to be avoided. Specifically, elution of components of the first magnetic material portion 301 and the ceramic substrate 100 into the plating solution to form the plating layer as the wiring portion 441 is more likely to be avoided.

While the core substrate 606 in Embodiment 6 is used as the core substrate of the interposer in the present embodiment, the core substrate in another embodiment may be used.

### Embodiment 12

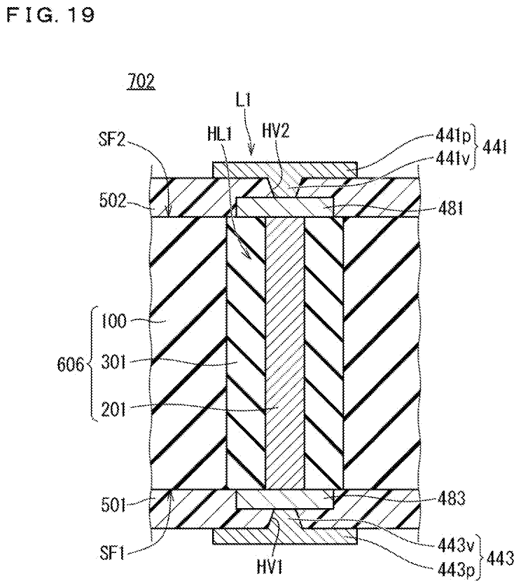

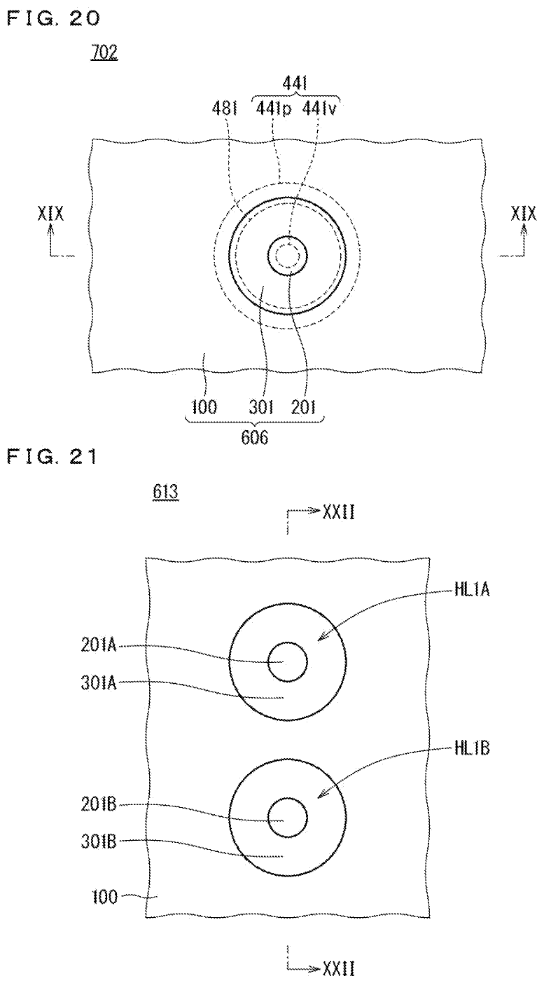

FIG. 19 is a diagram schematically showing a configuration of an interposer 702 in Embodiment 12, and is a partial cross-sectional view taken along the line XIX-XIX of FIG. 20. FIG. 20 is a partial plan view schematically showing a configuration of the second surface SF2 of the interposer 702 in FIG. 19. The interposer 702 is one example of the interposer 700 (FIG. 1 or 2). Specifically, the interposer 702 includes the core substrate 606 (FIG. 12: Embodiment 6), the wiring portion 441, the insulator layer 502, and an electrode pad 481 as the wiring layer 791 (FIG. 1 or 2), and the wiring portion 443, the insulator layer 501, and an electrode pad 483 as the wiring layer 792 (FIG. 1 or 2). In FIG. 20, the configuration of the core substrate 606 is indicated by solid lines, and another configuration added to the core substrate 606 is indicated by dashed lines for clarity of illustration.

The electrode pad 481 is connected to the first conductor portion 201 of the core substrate 606. The bottom surface of the connecting via 441v of the wiring portion 441 is connected to the electrode pad 481 in the present embodiment in contrast to Embodiment 11 described above. The bottom surface of the connecting via 441v is separated from the first magnetic material portion 301 and the ceramic substrate 100. The electrode pad 481 covers the first conductor portion 201. The electrode pad 481 may have a portion covering the first magnetic material portion 301. Specifically, the electrode pad 481 may partially cover the first magnetic material portion 301 along the second surface SF2 as illustrated in FIG. 19. In this case, an edge of the electrode pad 481 is disposed on the first magnetic material portion 301 as illustrated in FIGS. 19 and 20. As a modification, the electrode pad 481 may exactly cover the first magnetic material portion 301 along the second surface SF2, and, in this case, the edge of the electrode pad 481 is disposed on a boundary between the first magnetic material portion 301 and the ceramic substrate 100. As another modification, the electrode pad 481 may cover the first magnetic material portion 301 while having a margin, and, in this case, the edge of the electrode pad 481 is disposed on the ceramic substrate 100 away from the above-mentioned boundary. The electrode pad 481 is a sintered metal layer. The sintered metal layer can be formed by printing and sintering of a paste layer. The electrode pad 481 may contain silver, copper, or a silver-copper alloy as a main component, and may be a sintered silver layer, a sintered copper layer, or a sintered silver-copper alloy layer, for example.

Similarly, the electrode pad 483 is connected to the first conductor portion 201 of the core substrate 606. The bottom surface of the connecting via 443v of the wiring portion 443 is connected to the electrode pad 483 in the present embodiment in contrast to Embodiment 11 described above. The bottom surface of the connecting via 443v is separated from the first magnetic material portion 301 and the ceramic substrate 100. The electrode pad 483 covers the first conductor portion 201. The electrode pad 483 may have a portion covering the first magnetic material portion 301. Specifically, the electrode pad 483 may partially cover the first magnetic material portion 301 along the first surface SF1 as illustrated in FIG. 19. In this case, an edge of the electrode pad 483 is disposed on the first magnetic material portion 301 as illustrated in FIG. 19. As a modification, the electrode pad 483 may exactly cover the first magnetic material portion 301 along the first surface SF1, and, in this case, the edge of the electrode pad 483 is disposed on a boundary between the first magnetic material portion 301 and the ceramic substrate 100. As another modification, the electrode pad 483 may cover the first magnetic material portion 301 while having a margin, and, in this case, the edge of the electrode pad 483 is disposed on the ceramic substrate 100 away from the above-mentioned boundary. The electrode pad 483 is a sintered metal layer. The electrode pad 483 may contain silver, copper, or a silver-copper alloy as a main component, and may be a sintered silver layer, a sintered copper layer, or a sintered silver-copper alloy layer, for example.

The other configuration is substantially the same as the above-mentioned configuration in Embodiment 11, so that the same or corresponding components bear the same reference signs, and description thereof is not repeated.

According to the present embodiment, the bottom surface of the connecting via 441v is separated from the magnetic material portion 301 and the ceramic substrate 100. Specifically, the insulator layer 502 and the electrode pad 481 separate the wiring portion 441 and each of the first magnetic material portion 301 and the ceramic substrate 100 of the core substrate 606. Inclusion of components of the first magnetic material portion 301 and the ceramic substrate 100 into the wiring portion 441 can thereby be avoided. Specifically, elution of components of the first magnetic material portion 301 and the ceramic substrate 100 into the plating solution to form the plating layer as the wiring portion 441 can be avoided. Variation of the electrical characteristics, in particular, conductivity of the wiring portion 441 can thereby be suppressed. The same applies to the wiring portion 443.

When the electrode pad 481 has the portion covering the first magnetic material portion 301, inclusion of components of the first magnetic material portion 301 can more reliably be avoided. The same applies to the electrode pad 483.

When the electrode pad 481 contains silver, copper, or the silver-copper alloy as a main component, inclusion of components of the electrode pad 481 into the wiring portion 441 is likely to be avoided. Specifically, elution of components of the electrode pad 481 into the plating solution to form the plating layer as the wiring portion 441 is likely to be avoided. Variation of the electrical characteristics (in particular, conductivity) of the wiring portion 441 can thereby more reliably be suppressed. The effect can more reliably be obtained when the electrode pad 481 is substantially made of silver or copper. The effect can also more reliably be obtained when the electrode pad 481 is the sintered silver layer or the sintered copper layer. The electrode pad 481 is thus preferably the sintered silver layer. The same applies to the electrode pad 483.

While the core substrate 606 in Embodiment 6 is used as the core substrate of the interposer in the present embodiment, the core substrate in another embodiment may be used.

### Embodiment 13

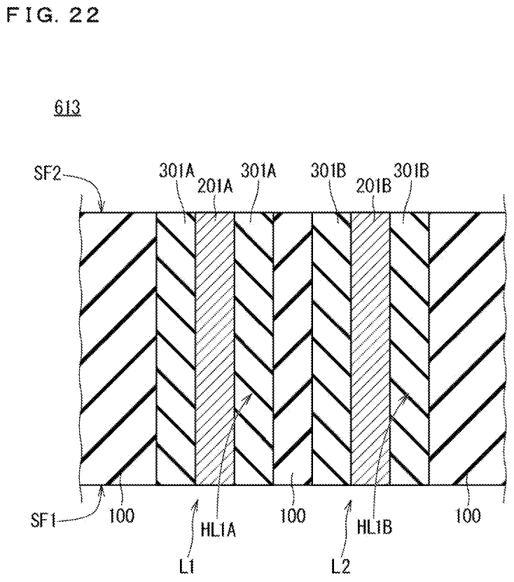

FIG. 21 is a partial plan view schematically showing a configuration of a core substrate 613 in Embodiment 13. FIG. 22 is a partial cross-sectional view taken along the line XXII-XXII of FIG. 21. The core substrate 613 includes the two inductors L1 and L2 (FIG. 22). The inductor L1 includes a conductor portion 201A and a magnetic material portion 301A provided within a through hole HL1A. The inductor L2 includes a conductor portion 201B and a magnetic material portion 301B provided within a through hole HL1B. The magnetic material portion 301A and the magnetic material portion 301B are away from each other. Specifically, the magnetic material portion 301A and the magnetic material portion 301B are separated by the ceramic substrate 100. Each of the inductors L1 and L2 of the core substrate 613 may have a similar configuration to the inductor L1 of the core substrate 606 (FIG. 12: Embodiment 6).

### Embodiment 14

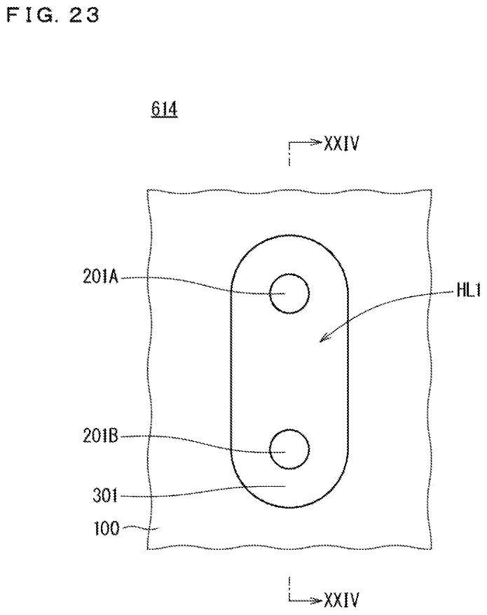

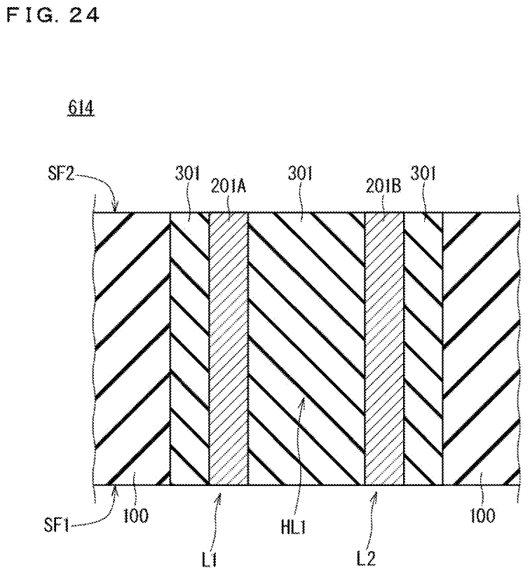

FIG. 23 is a partial plan view schematically showing a configuration of a core substrate 614 in Embodiment 14. FIG. 24 is a partial cross-sectional view taken along the line XXIV-XXIV of FIG. 23. The core substrate 614 includes the two inductors L1 and L2 (FIG. 24). As in Embodiment 13 described above, the inductor L1 and the inductor L2 respectively include the conductor portion 201A and the conductor portion 201B in the present embodiment. On the other hand, in contrast to Embodiment 13 described above, the inductors L1 and L2 share the magnetic material portion 301 provided within the through hole HL1 in Embodiment 14. The conductor portion 201A and the conductor portion 201B are thus separated not by the ceramic substrate 100 but by the magnetic material portion 301.

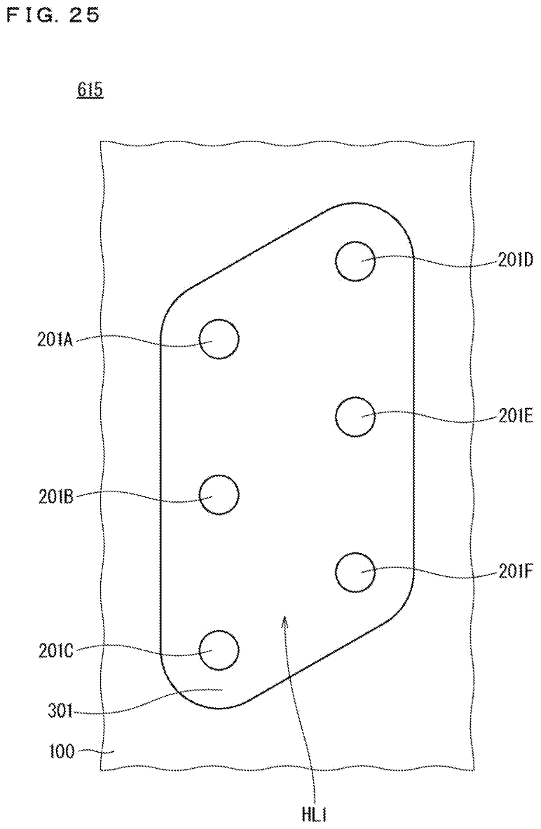

The number of conductor portions provided within the common magnetic material portion 301 is not limited to two as illustrated in FIG. 23. FIG. 25 is a partial plan view illustrating a modification of FIG. 23. In the present modification, six conductor portions 201A to 201F are provided within the common magnetic material portion 301.

Arrangement thereof includes arrangement along a first direction (vertical direction in FIG. 25) and arrangement along a second direction (diagonal direction in FIG. 25).

A configuration in which a plurality of conductor portions are arranged within a common magnetic material portion as in the present embodiment may be applied to the core substrate in any of Embodiments 1 to 12 described above.

The above-mentioned embodiments and modifications may freely be combined with each other. While the invention has been described in detail, the foregoing description is in all aspects illustrative and not restrictive. It is understood that numerous unillustrated modifications can be devised without departing from the scope of the present invention.

What is claimed is:

1. A core substrate with a built-in inductor, the core substrate being for constructing an interposer to which a semiconductor element is mounted, the core substrate comprising:
a ceramic substrate having a first surface, a second surface opposite the first surface in a thickness direction, and a through hole between the first surface and the second surface;
a conductor portion extending through the through hole; and
a magnetic material portion surrounding the conductor portion within the through hole, and made of ceramics, wherein
the conductor portion is made of sintered metal.

2. The core substrate according to claim 1, wherein
the conductor portion is a non-hollow body.

3. The core substrate according to claim 1, wherein
the conductor portion and the magnetic material portion are bonded together without an organic material interposed therebetween.

4. The core substrate according to claim 1, wherein
the conductor portion and the magnetic material portion are inorganically bonded together.

5. The core substrate according to claim 1, wherein
the conductor portion and the magnetic material portion are sintered together.

6. An interposer comprising:
the core substrate according to claim 1; and
a wiring portion including a connecting via having a bottom surface connected to the conductor portion of the core substrate, wherein
the bottom surface of the connecting via is separated from the magnetic material portion and the ceramic substrate.

7. The interposer according to claim 6, further comprising
an insulator layer having a via hole in which the connecting via is disposed, wherein
the insulator layer separates the wiring portion and each of the magnetic material portion and the ceramic substrate of the core substrate.

8. The interposer according to claim 7, wherein
the via hole of the insulator layer is tapered toward the conductor portion.

9. The interposer according to claim 7, wherein
the insulator layer contains organic matter.

10. The interposer according to claim 6, wherein
the wiring portion is a plating layer.

11. An interposer comprising:
the core substrate according to claim 1;
an electrode pad connected to the conductor portion of the core substrate; and
a wiring portion including a connecting via having a bottom surface connected to the electrode pad, wherein
the bottom surface of the connecting via is separated from the magnetic material portion and the ceramic substrate.

12. The interposer according to claim 11, wherein
the electrode pad has a portion covering the magnetic material portion.

13. The interposer according to claim 11, wherein
the electrode pad contains silver.

14. The interposer according to claim 11, wherein
the electrode pad is a sintered metal layer.

15. The interposer according to claim 11, wherein
the wiring portion is a plating layer.
